(19) United States
(12) Patent Application Publication
(10) Pub. No.: US 2025/0236105 A1
(43) Pub. Date: Jul. 24, 2025

(54) Transferable Nanostructure Fabrication by Gapless Stencil Lithography

(71) Applicant: Massachusetts Institute of Technology, Cambridge, MA (US)

(72) Inventors: Riccardo Comin, Cambridge, MA (US); Ahmet Kemal Demir, Boston, MA (US); Jiaruo Li, Cambridge, MA (US)

(73) Assignee: Massachusetts Institute of Technology, Cambridge, MA (US)

(21) Appl. No.: 18/951,806

(22) Filed: Nov. 19, 2024

Related U.S. Application Data
(60) Provisional application No. 63/622,619, filed on Jan. 19, 2024.

(51) Int. Cl. B41F 15/08; B41F 15/36; G03F 7/00; G03F 7/12

(52) U.S. Cl. CPC B41F 15/0813; B41F 15/36; G03F 7/0002; G03F 7/0015; G03F 7/12; G03F 7/70008; G03F 7/70383

(57) ABSTRACT

Optical spectroscopy can unveil the unique properties and symmetries of materials in the atomically thin limit. However, these materials often have cross sections too low for conventional optical spectroscopy. Here, we disclose gapless stencil lithography techniques for fabricating transferable, high-resolution nanostructures for Raman and photoluminescence (PL) spectroscopy. Using these nanofabrication techniques, we designed and fabricated plasmonic nanostructures to tailor the interaction of atomically thin materials with light. These nanofabrication techniques are particularly suitable for optical studies of air-sensitive materials, as the fabrication and transfer can be performed in situ. Our nanofabrication techniques can also be used to make other transferable functional photonic devices and transfer them to surfaces of other materials. Our transferable ultrathin membranes can be stacked on top of one another to decrease the minimum feature size of nanofabrication to under 10 nm.

### CROSS-REFERENCE TO RELATED APPLICATION(S)

This application claims the priority benefit, under 35 U.S.C. 119 (e), of U.S. Application No. 63/622,619, filed Jan. 19, 2024, which is incorporated herein by reference in its entirety for all purposes.

### STATEMENT OF GOVERNMENT RIGHTS

This invention was made with government support under DE-SC0012704 awarded by the U.S. Department of Energy. The government has certain rights in the invention.

### BACKGROUND

Optical techniques play an essential role in the investigation, characterization, and modification of materials. Discovery of various magnetic ground states in two-dimensional materials, extremely sensitive magnetometry using diamond nitrogen vacancy (NV) centers, detecting biomarkers in living systems for the study of cell dynamics and development, data storage and read-out from wide-gap semiconductors, solar cell characterization, and countless more examples can be attributed to the success of appropriate integration of optical methods in experiments.

Raman and photoluminescence (PL) spectroscopy, for example, can enable the determination of ground state symmetries and their associated excitations, crystallographic orientations, number of layers, and many more characteristics of solids, all in a nondestructive fashion without the need for contact. Although a very common technique in atomically thin materials research, one challenge of using Raman spectroscopy is that the cross section for Raman scattering is usually very small, which translates to very small Raman signals for most materials; a problem that is exacerbated for low dimensional materials.

A practical solution to the low cross section problem is to use plasmonic metal nanostructures placed near the sample to enhance the field and modify the spontaneous emission rate of the emitters. This approach, called surface enhanced Raman spectroscopy (SERS), increases the amplitude of the Raman signal by orders of magnitude. As the Raman signal is roughly correlated with the amount of matter interacting with light, two-dimensional materials are a great platform for SERS. (Two-dimensional materials are substances with a thickness of a few nanometers or less. Electrons in a two-dimensional material are free to move in the plane of the two-dimensional material, but their motion out of the plane is restricted by quantum mechanics. Examples of 2D materials include quantum wells, graphene, tungsten diselenide, and hexagonal boron nitride.) Metal nanoparticles have been fabricated directly on graphene. This fabrication method, however, is destructive and not generalizable to other materials, including air-sensitive materials. To harness the full potential of surface-enhanced spectroscopy methods, a versatile, sample-independent, and non-destructive method of forming plasmonic metal nanostructures is needed.

### SUMMARY

One solution to the problem of integrating photonic nanostructures with different materials is to transfer the nanostructures onto the materials—in other words, to render both the nanostructures and the materials mobile. This is a challenge, however, as most methods of making plasmonic nanostructures rely on an adhesion layer to stick the nanostructure to the substrate on which the nanostructure is formed to preserve the nanostructure's intended shape. Unfortunately, this adhesion layer immobilizes the nanostructure on the substrate, making it difficult or impossible to transfer the nanostructure to another substrate. If the adhesion layer is eliminated, significant blurring and deformation ensue, especially for conventional stencil lithography, which involves depositing material onto a substrate through apertures in a stencil suspended above (i.e., not touching) the substrate. Conventional stencil lithography is relatively simple and does not involve chemical or thermal treatment.

Fortunately, these problems and challenges can be addressed by gapless stencil nanofabrication methods that include patterning a stencil for nanostructures, placing the stencil in direct contact with a surface of a substrate, depositing material through the stencil directly on the surface of the substrate to form the nanostructures, and removing the stencil from the substrate. The stencil can be patterned from a membrane, such as a silicon or silicon nitride membrane with a thickness of about 10 nm to about 500 nm, using focused ion beam milling. Since these stencils can be so thin (e.g., 10 nm), they can be patterned to provide a low aspect ratio of mask height to mask feature size. If the nanostructures adhere to the substrate via van der Waals bonding, they can be mechanically transferred from the substrate (e.g., a silicon and/or silicon oxide substrate) to a sample (e.g., a two-dimensional and/or air-sensitive material). The stencil can be lifted off the substrate with a piece of adhesive tape and disposed or used to form additional nanostructures. The stencil itself is transferable, using the same transfer methods, allowing the stacking the stencils on top of one another to enhance the resolution of lithography by decreasing feature size. The stencil can also be etched away using reactive ion etching or another suitable technique, leaving the nanostructures behind.

All combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. The terminology explicitly employed herein that also may appear in any disclosure incorporated by reference should be accorded a meaning most consistent with the particular concepts disclosed herein.

### BRIEF DESCRIPTIONS OF THE DRAWINGS

The skilled artisan will understand that the drawings primarily are for illustrative purposes and are not intended to limit the scope of the inventive subject matter described herein. The drawings are not necessarily to scale; in some instances, various aspects of the inventive subject matter disclosed herein may be shown exaggerated or enlarged in the drawings to facilitate an understanding of different features. In the drawings, like reference characters generally refer to like features (e.g., functionally similar and/or structurally similar components).

FIG. 1A illustrates making and transferring nanostructures using gapless stencil lithography.

FIG. 1B shows scanning electron microscope (SEM) images taken at different steps of the fabrication process shown in FIG. 1A, shown in order: the milled membrane, or stencil; the sides of the stencil are cut off with a focused ion beam (FIB); before the stencil is removed from the sacrificial substrate on which it is made; after the stencil is removed from the sacrificial substrate; and after the nanostructures are transferred from the sacrificial substrate to a single-layer WSe₂ sample.

FIG. 1C illustrates an alternative gapless stencil lithography method of making nanostructures.

FIG. 1D shows SEM and optical images taken at different steps of the fabrication process shown in FIG. 1C, shown in order: milled membrane (stencil); the sides of the stencil are cut with a FIB; the stencil on a sacrificial chip (optical image); the stencil is transferred onto a sample (optical image); gold deposited through the stencil and onto the sample; and gold nanostructures after the stencil has been removed from the sample.

FIG. 2A illustrates perspective (top) and plan (bottom) views of placing one stencil on top of an identical stencil, each with a two-dimensional square array of circular apertures, at an angle to form apertures that are smaller than those that can be formed in the stencils.

FIG. 2B shows plan views of pairs of identical stencils, each with a two-dimensional square array of circular apertures, stacked together and twisted or rotated with respect to each other at angles of 5°, 10°, 15°, and 20° to form apertures of different shapes and sizes.

FIG. 2C shows a plan view of a stencil with a two-dimensional square array of circular apertures and a stencil with an asymmetric array of apertures that are translated and twisted with respect to each other and stacked together.

FIG. 2D shows a plan view of two stencils with identical asymmetric arrays of apertures that are translated and twisted with respect to each other and stacked together.

FIG. 2E is a scanning electron microscope (SEM) image of two 30-nm-thick SiN membranes, patterned with square arrays of circular holes with diameters over 120 nm, stacked on top of one another and rotated relative to each other by about 9.5°.

FIG. 3A is an SEM image of gold nanodisks deposited on a substrate with a stencil or mask that was not in direct contact with the substrate.

FIG. 3B is an SEM image of gold nanodisks deposited on a substrate with a stencil or mask that was in direct contact with the substrate.

FIG. 3C is an SEM image of a bifunctional metasurface fabricated on a substrate using stencil lithography with an adhesion layer and the stencil separated from the substrate by gap (i.e., the stencil and sample are not in direct contact with each other) as described in Ding, F et al. Light Sci Appl 7, 17178 (2018), which is incorporated herein by reference in its entirety for all purposes.

FIG. 3D is an SEM image of a bifunctional metasurface made with gapless stencil lithography.

FIG. 4A is a simulation of the electric field enhancement from a transferred gold nanodisk with radius R=90 nm, thickness=20 nm. The position of the nanodisk is delineated by the dashed line.

FIG. 4B is a plot of wavelength-dependent normalized scattering cross sections for gold nanodisks of different radii and the same thickness, 20 nm.

FIG. 4C shows raw Raman spectra of WSe₂ taken with 785 nm excitation with and without the nanodisks for a gold filling factor of 0.32. The low wavenumber tail is the intralayer exciton of WSe₂. The inset shows an optical micrograph of the arrays of nanostructures, with the radii of the nanodisks typed on the arrays.

FIG. 4D shows raw Raman spectra of three-layer NiI₂ taken with 785 nm excitation with and without nanodisks. The inset shows the optical micrograph of the structure, with the regions of interest delineated and labeled.

FIG. 4E shows the Raman spectrum of bulk NiI₂ taken with 785 nm excitation.

FIG. 5 shows an SEM image of transferred gold nanodisks (left) and an atomic force microscope (AFM) image (right) of a portion of the transferred gold nanodisks.

FIG. 6A shows an SEM image of transferred plasmonic nanodisk arrays on MoS₂.

FIG. 6B shows an optical image of the transferred plasmonic nanodisk arrays on MoS₂ of FIG. 6A.

FIG. 6C is a plot of Raman count versus wavenumber for bare MoS₂ (lower trace) and transferred plasmonic nanodisk arrays on MoS₂ (upper trace).

FIG. 7A is an optical micrograph of a WSe₂/MoS₂ heterostructure below a transferred gold nanodisk array.

FIG. 7B shows photoluminescence (PL) spectra of MoS₂, WSe₂, and the heterostructure of FIG. 7A. The PL signal from intralayer excitons is quenched by about two orders of magnitude.

FIG. 7C shows PL spectra of the heterostructure taken on and off the gold nanodisk nanoarray showing about an order of magnitude increase in the PL from the exciton emission wavelength to which the gold nanodisks were tuned.

FIG. 7D shows the Raman spectrum (using 532 nm excitation) of the heterostructure shown in FIG. 7A (interlayer modes are ascribed to the coupling of the layers in the heterostructure).

FIG. 8A shows Raman spectra (using 785 nm excitation) on (upper trace) and off (lower trace) the transferred gold nanodisks on the heterostructure shown in FIG. 7A.

FIG. 8B is a polar plot of the polarization-independent enhancement on (outer trace) and off (inner trace) the transferred gold nanodisks on the heterostructure shown in FIG. 7A.

FIG. 9A illustrates the calculation of near-field enhancement with a plane wave excitation at a wavelength of 785 nm for a gold nanodisk in a transferred nanodisk array.

FIG. 9B is a plot of simulated SERS enhancement factor (EF) values using the |E|⁴ approximation for gold nanodisks of different radii.

FIG. 9C is a plot of measured EF values for gold nanodisks of different radii.

FIG. 9D illustrates the calculation of Purcell enhancement factors with a dipole excitation with a given wavelength and distance for a gold nanodisk in a transferred nanodisk array.

FIG. 9E is a plot of simulated PL enhancement for a bare heterostructure (bottom trace), a control gold nanodisk array (middle trace), and a tuned gold nanodisk array (top trace).

FIG. 9F is a plot of measured PL enhancement for a bare heterostructure (bottom trace), a control gold nanodisk array (middle trace), and a tuned gold nanodisk array (top trace).

FIG. 10 is a plot of simulated EF versus nanodisk radius for an explicit calculation of the Purcell factor (lower trace) and an |E|⁴ approximation (upper trace).

FIG. 11 is a plot of Raman counts versus laser power of the E_{2g} phonon on 90 nm radius gold nanodisks.

FIG. 12A is an optical micrograph of transferred silver (Ag) nanodisks (radius=70 nm, thickness=38 nm) on monolayer WSe₂ on a quartz substrate.

FIG. 12B is a plot of Raman count versus wavenumber for the transferred silver nanodisks and monolayer WSe₂ of FIG. 12A.

### DETAILED DESCRIPTION

Here, we present nanofabrication methods that address difficulties with conventional stencil lithography by eliminating the adhesion layer used to secure the nanostructures to the substrate and placing the stencil directly on the substrate or sample. These nanofabrication methods, which we call gapless stencil lithography, preserve the shape of the intended nanostructures in a simple-to-implement, resist-free fashion. The resulting nanostructures are weakly bonded to the surface of a sacrificial substrate by van der Waals (vdW) forces with the appropriate selection of the deposited material and the sacrificial substrate. This renders polymer stamp transfer techniques, widely employed in heterostructures and quantum devices research, feasible for transferring the nanostructures from the sacrificial substrate to another surface.

Gapless stencil lithography enables the integration of nanostructures, such as nanoscale photonic devices, with atomically thin materials. These nanostructures can be functionalized for deterministically enhancing the optical response of a variety of materials by tuning the transferable plasmonic structures to certain wavelengths of interest. They can enhance Raman and photoluminescent (PL) modes in a spatially selective way. Since the nanostructures can be transferred from a sacrificial chip to the sample in a glovebox, gapless stencil nanofabrication is particularly attractive for the forming nanostructures on air-sensitive, atomically thin materials. It can be used with little to no change of parameters for optical enhancement of spectroscopy methods other than Raman and PL, like second-harmonic generation and absorption, and can be used to increase signal amplitude by orders of magnitude. Combining the highly deterministic characteristics of the technique with vastly increased mobility of the nanostructures, our gapless stencil nanofabrication methods can be used for fabricating complex metasurfaces and photonic structures and find uses in quantum information technologies with optical read-outs.

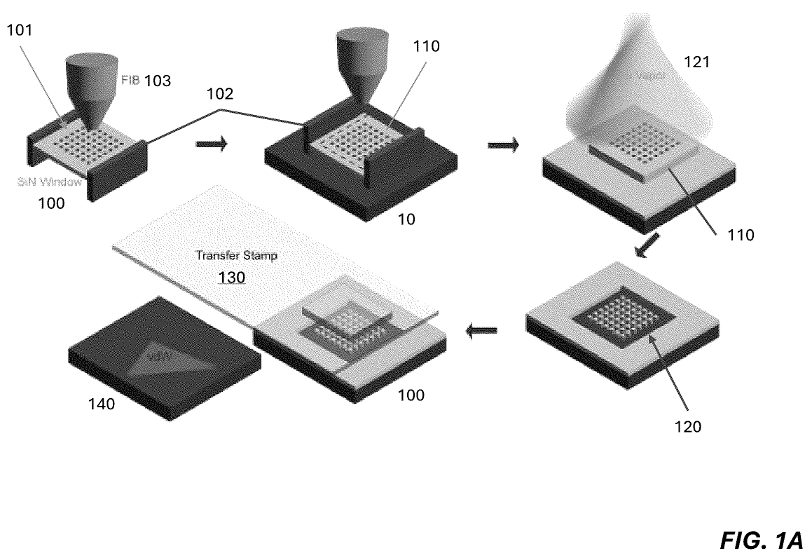

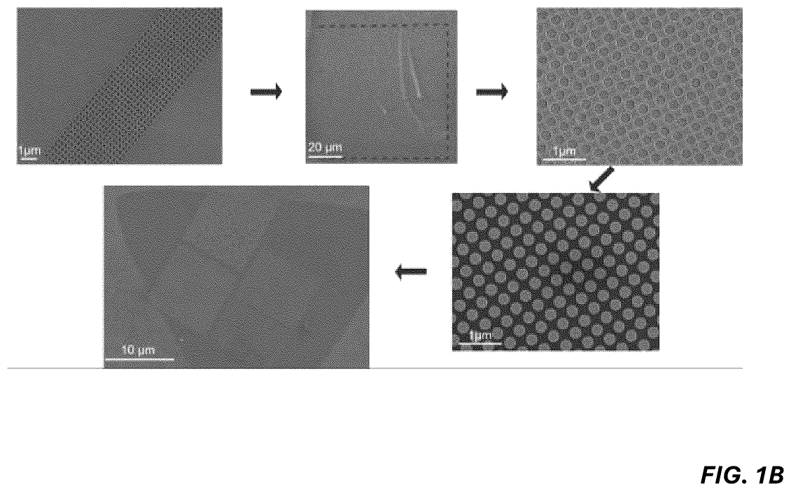

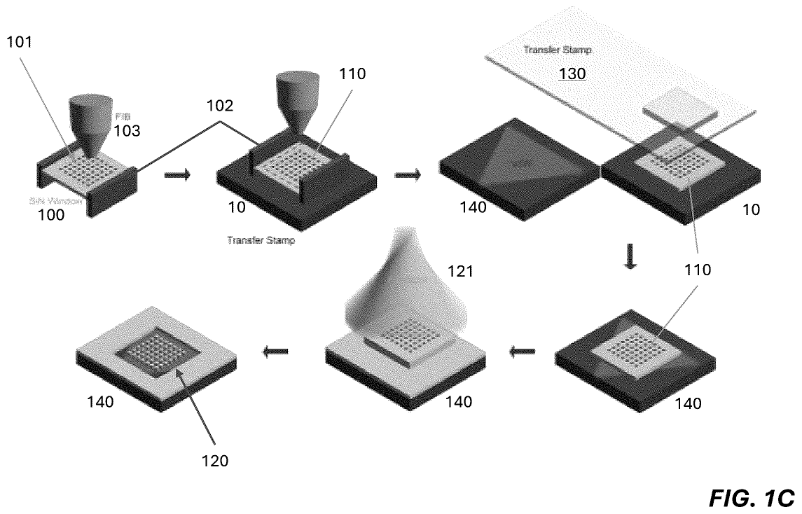

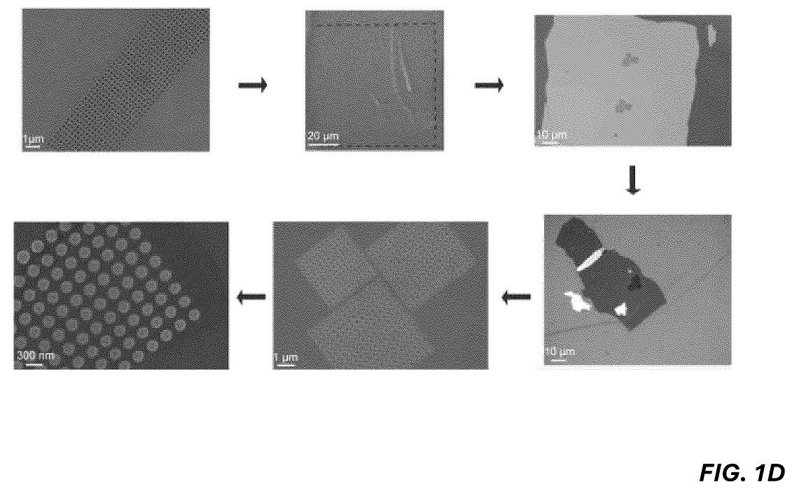

FIG. 1A illustrates one embodiment of our method for making transferrable nanostructures 120. This embodiment of our method starts (upper left, FIG. 1A) with creating a stencil, mask, or mold 110 for the nanostructures by imprinting or lithographically patterning holes or apertures 101 in a negative of the desired nanostructure shape(s) on a membrane 100, such as a commercially available silicon or silicon nitride membrane like those employed for transmission electron microscopy (TEM) imaging. Apertures 101 in nanostructure shape(s) can be imprinted on the membrane 100 using focused ion beam (FIB) milling 103, but any lithography technique capable of drilling through the membrane 100 should work for imprinting the shape(s) on the membrane 100, including electron-beam lithography. During milling, the membrane 100 is supported by a window 102 made of silicon or another suitable material (indicated by the rectangular blocks 102 holding the milled membrane at upper left in FIG. 1A). The thickness of the membrane 100 is the natural upper bound for the thickness of the nanostructures 120 and can range from about 10 nm to up to about 500 nm.

After the lithography on the membrane's top surface, we flip the patterned membrane, now also called the stencil 110, and place it directly on an atomically flat surface of a sacrificial substrate 10, such as an Si/SiO₂ substrate (upper middle, FIG. 1A). The choice of the sacrificial substrate 10 is arbitrary, provided that the material to be deposited through the stencil 110 (i.e., the nanostructure material) on the sacrificial substrate's surface does not form strong bonds with the sacrificial substrate's surface. Next, we mill away the edges of the stencil 110 (indicated by dashed lines in FIG. 1A), which are typically a couple of microns away from the surface of the sacrificial substrate 10, so that the stencil 110 is in direct contact with the surface of the sacrificial substrate 10. (Conversely, in conventional stencil lithography, there is a gap between the stencil and the substrate upon which the material is deposited.) The stencil 110 sticks to the surface of the sacrificial substrate 10 well enough not to fall off the sacrificial substrate 10 when the stencil 110 and sacrificial substrate 10 are placed upside down in the deposition chamber. Milling away the stencil sides severs the connection between the window 102 and the stencil 110, so the window 102 can just be lifted away, e.g., with tweezers. The stencil 110 can also be picked up from the window 102 directly with a transfer stamp made from a polymer (e.g., PDMS) and dropped off the transfer stamp in contact with the substrate 10.

We then deposit the nanostructure material (e.g., gold 121) on the substrate 10 through the stencil 110 using electron beam evaporation, sputtering, vapor deposition/transport, or another suitable technique (upper right, FIG. 1A). Both gold and silver deposition on a SiO₂ substrate yield precise and transferable nanostructures 120. Because the stencil 110 is so thin (e.g., 10, 20, or 30 nm thick), it can have a much lower aspect ratio than the photoresist layer used in conventional patterning techniques and can produce nanostructures 120 with much finer resolution. Suitable nanostructure materials include materials that do not form chemical bonds with the sacrificial substrate, e.g., gold or silver for a Si/SiO₂ substrate. Other suitable materials include Al, Al₂O₃, C, Cr, Co, Cu, Ge, Fe, Mo, Ni, Pd, Permalloy, Pt, Si, SiO₂, Ta, Ti, TiO₂, W, and WO, depending on the sacrificial substrate and the sample onto which the nanostructures 120 will ultimately be transferred. The evaporated material fills up the apertures 101 in the stencil 110 fabricated earlier by the FIB milling 103. Using a low-adhesion tape or other sticky substance (e.g., polycarbonate, polydimethylsiloxane, polypropylene; not shown), we peel the stencil 110 off of the sacrificial substrate 10, which leaves the nanostructures 120 on the sacrificial substrate's surface, ready for the transfer (lower right, FIG. 1A). If the stencil 110 is a single-use stencil, it can be discarded; if not, it can be used to create more nanostructures 120, either on the original sacrificial substrate 10 or on a different substrate.

We use a polycarbonate/polydimethylsiloxane (PC/PDMS) stamp 130 to transfer the nanostructures 120 from the sacrificial substrate's surface directly to the surface of a sample 140 (lower left, FIG. 1A), which may be a 2D material and/or air-sensitive. If the nanostructures 120 or the sample 140 are heat-sensitive, then the nanostructures 120 can be transferred directly to the surface the sample 140 using a cold transfer technique. With either type of transfer technique, van der Waals (vdW) forces adhere the nanostructures 120 to the surface of the sample 140. That is, unlike with conventional techniques, there is no adhesive layer between the nanostructures 120 and the sample 140.

FIG. 1B shows scanning electron microscopy (SEM) images of the stencil and nanostructures at different points in the process of FIG. 1A. The stencil is made from a SiNₓ membrane, which was milled, flipped, and lowered into direct contact with a sacrificial Si/SiO₂ substrate. The window supporting the stencil was removed, and gold was evaporated onto the Si/SiO₂ substrate through the stencil to form gold nanostructures. The stencil was loosely stuck to the surface of the Si/SiO₂ substrate and was removed easily with a low-adhesion tape. The gold nanostructures were then transferred onto a single-layer WSe₂ sample.

FIGS. 1C and 1D illustrate an alternative embodiment of gapless stencil lithography. In this embodiment, the stencil 110 is milled or patterned into a membrane 100 (e.g., a SiNₓ membrane) using FIB milling 103 or another suitable technique (upper left, FIG. 1C), then flipped and placed directly in contact with the surface of a sacrificial substrate 10 as in FIG. 1A (upper middle, FIG. 1C). The window 102 is removed from the patterned membrane to yield the finished stencil 110, which is transferred directly onto the surface of the sample 140 (upper right and lower right, FIG. 1A). Unlike with conventional techniques, there is no adhesion layer, other material, or gap between the stencil 110 and the surface of the sample 140. Transferring the stencil 110 from the sacrificial chip 10 to the sample of interest 140 is a much more precise approach than cutting the membrane over the sample of interest. This approach also ensures that there is no ion damage to the sample 140 while cutting the stencil 110.

The nanostructure material (e.g., gold or silver) 121 is then deposited directly onto the sample's surface through the stencil 110 (lower middle, FIG. 1C), which can be removed easily with low-adhesion tape (lower right, FIG. 1C). Because the nanostructures 120 are formed directly on the sample 140, they do not need to be transferred. As a result, the process illustrated in FIG. 1C works with any material that can be evaporated, including materials that do form chemical bonds with the sample 140.

FIG. 1D shows SEM and optical images of the stencil and nanostructures at different points in the process of FIG. 1C. The stencil is made from a SiNₓ membrane, which was milled (upper left, FIG. 1D) on a sacrificial substrate. The window supporting the patterned SiNₓ membrane were removed to yield the stencil (upper middle, FIG. 1D), which was then flipped and placed in direct contact with the surface of a sample (upper right and lower right, FIG. 1D). Gold was then deposited through holes in the stencil directly on the sample surface (lower middle, FIG. 1D) before the stencil was removed from the sample with a piece of tape, leaving the nanostructures directly on the sample surface (lower left, FIG. 1D).

### Stacking Stencils

One advantage of gapless stencil lithography shown in FIGS. 1A-ID over conventional wet lithography methods without adhesion layers, apart from the absence of chemical treatment, is that the stencils themselves are also transferable. This is consequential in many ways: the stencils can be used as mobile photonic structures themselves (such as bound state in the continuum-hosting surfaces) or can be transferred, using usual polymer stamp techniques, onto the material of interest before the deposition of the nanostructure material (e.g., metal), which provides great flexibility over the integration of photonic nanostructures and materials. A single stencil and sacrificial substrate can also be used over and over again to make many sets of nanostructures: once the nanostructures have been removed from the sacrificial substrate, the stencil can be disposed directly on the sacrificial substrate's surface again (or on a different surface of the sacrificial substrate or on a different sacrificial substrate) and used to make another set of nanostructures.

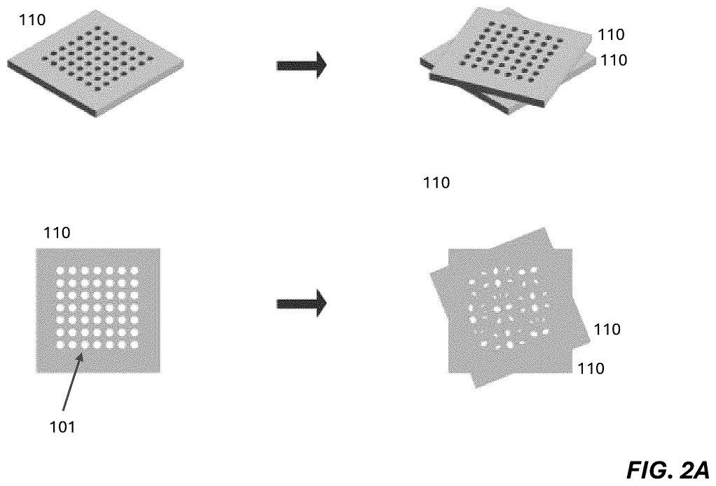

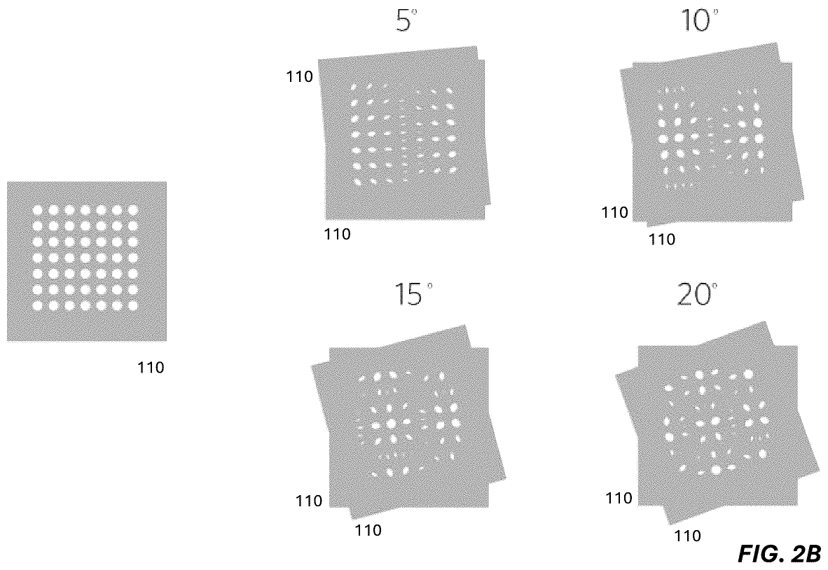

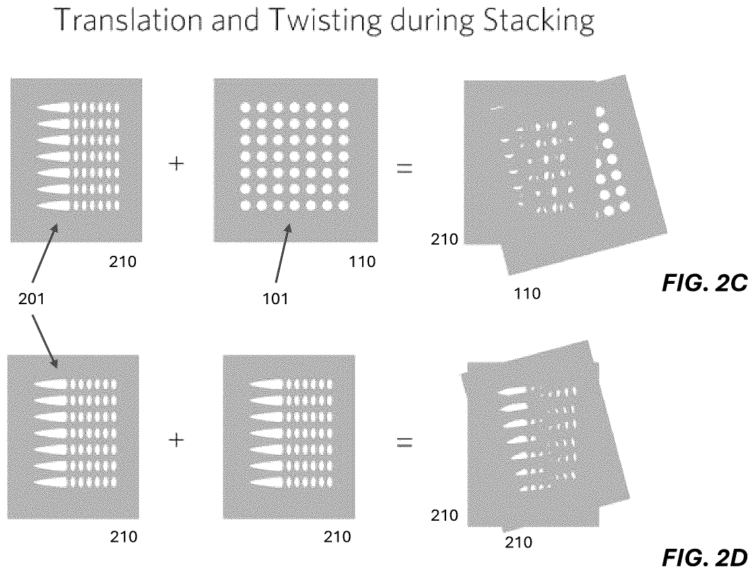

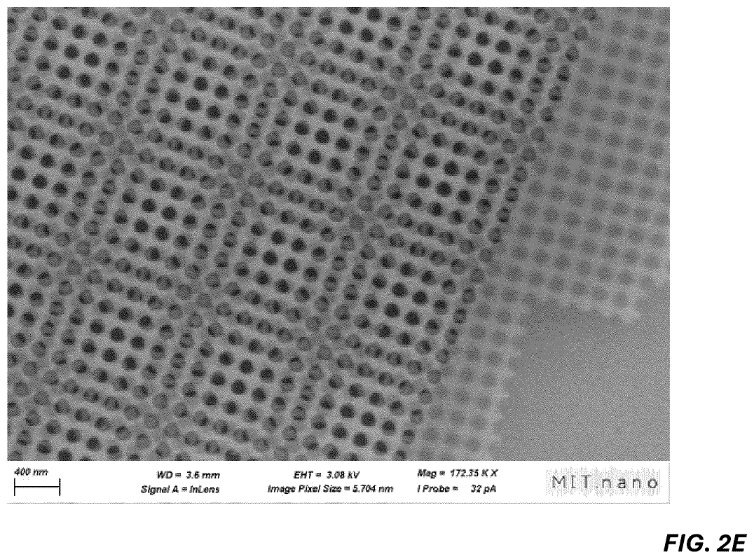

FIGS. 2A-2E illustrate another use for stacked stencils: they can be used to form nanostructures that are smaller or in more complex shapes than the holes patterned in the stencils using FIB or other patterning techniques. FIG. 2A shows how two identical stencils 110 with square arrays of circular holes 101 can be used to create nanostructures with lateral dimensions that are smaller than the diameters of the holes 101 and shapes that are not circular/cylindrical. The stencils 110 are stacked on top of each other on the surface of a sacrificial substrate or sample (not shown) and twisted or rotated about an axis that is perpendicular to the surface upon which they are placed as shown at right in FIG. 2A. The stencils 110 can also be shifted or translated with respect to each other in a direction parallel to the surface upon which they are placed. If desired, more than two stencils can be stacked together and twisted and/or translated, e.g., each by the same amount or by different amounts. The stencils can be identical or different, depending on the desired shapes and sizes of the nanostructures to be formed with the stacked stencils.

Twisting or rotating the stencils 110 causes the apertures 101 of the upper stencil 110 to partially occlude the apertures 101 of the lower stencil 110 as shown at lower right in FIG. 2A. When viewed along the axis perpendicular to the surface of the sacrificial substrate or sample, the overlapping apertures 101 form a kaleidoscopic or Moiré pattern with clear apertures that are smaller and different in shape than the circular holes 101 in the stencils 110. Material deposited through both of the stacked, twisted stencils 110 travels along this axis and so forms nanostructures whose cross-sections have the smaller, non-circular shapes of the clear apertures. These clear apertures can also be used as etch masks for patterning substrates with features that have sizes and/or shapes that are difficult or impossible to pattern using other techniques. Alternatively, material can be deposited through the lower stencil 110, then the upper stencil 110 can be place on the lower stencil 110. Depositing material through both stencils 110 forms offset nanostructures (e.g., nanostructures with cantilevered sections), and the stencils 110 can be dissolved to leave these cantilevered nanostructures in place.

FIG. 2B illustrates the effects of changing the twist or rotation angle. It shows plan views of a pair of stencils 110 with identical square arrays of circular holes stacked on top of each other and twisted or rotated at angles of 5°, 10°, 15°, and 20°. Changing the twist or rotation angle changes both the shapes and sizes of the clear apertures and hence the shapes and sizes of the nanostructures that can be fabricated by depositing gold or other material through the stencils.

FIGS. 2C and 2D illustrates the effects of using stencils with different patterns of holes and of translating the stencils laterally with respect to each other. In FIG. 2C, a stencil 110 with a square array of circular holes 110 is stacked on a stencil 210 with an asymmetric array of nonuniform holes 201 and both twisted and translated as shown at right to form clear apertures that are smaller and of different shapes than either the circular holes 101 or the nonuniform holes 201. In FIG. 2D, two stencils 210 with identical asymmetric arrays of nonuniform holes 201 are stacked on top of each other and both twisted and translated as shown at right to form clear apertures that are smaller and of different shapes than the nonuniform holes 201.

FIG. 2E is an SEM image of two 30-nm-thick SiN membranes, patterned with holes with diameters over 120 nm, stacked on top of one another and twisted with respect to each other by about 9.5°. The resulting array of holes has feature (aperture) sizes as small as 7-8 nm. This is more than an order of magnitude reduction in the feature (aperture) size. There may be even smaller features that cannot be resolved in SiN with SEM. All in all, stacking stencils can be utilized to go beyond the limits of the lithography tool used to define the stencils without multiple lithography and deposition/etching cycles-just a single lithography session and stacking multiple stencils in the matter of minutes. This is enabled by the easy and convenient transferability of the stencils with high precision. These stencils can be used for etching or deposition and can be used again as they can be picked up using the very same method. Since the membranes can be as thin as 10 nm, the ratio of the mask height to the feature size can be made small enough to prevent pinch-offs that arise due to larger aspect ratios common in conventional lithography techniques, enabling the fabrication of ultrasmall features.

Precision Nanostructures Made with Gapless Stencil Nanofabrication

Placing the membrane directly on the surface of the sacrificial substrate or the sample leads to another advantage of gapless stencil lithography: the nanostructures can be fabricated more precisely than in conventional stencil lithography. That is, with gapless stencil lithography, the nanostructures have neat, crisp edges and (nearly exactly) the same shapes and sizes as the holes or openings in the stencil. If the stencil is patterned with cylindrical holes with radii of 100 nm and heights of 200 nm, for example, then the nanofeatures are cylinders with radii of 100 nm and heights of 200 nm. Conversely, the gap between the stencil and the substrate surface in conventional stencil lithography allows the evaporated material to diffract or spread, smearing or blurring the edges of the patterned features.

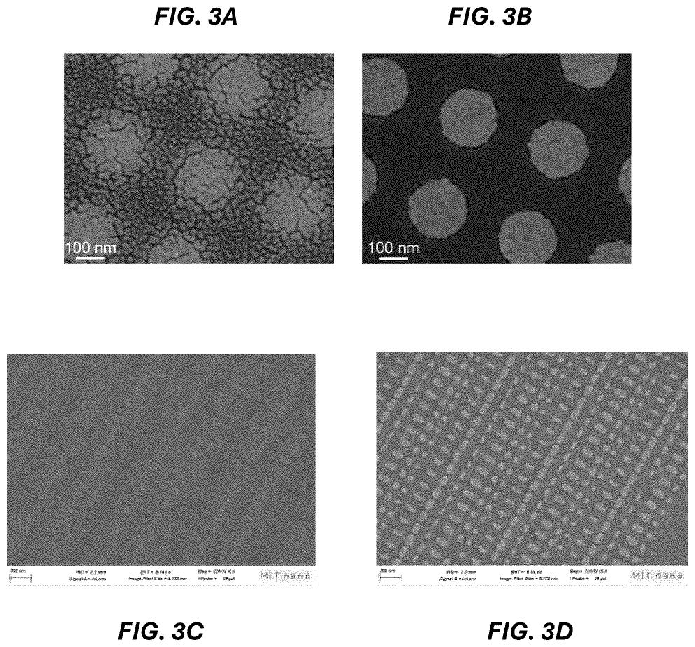

FIGS. 3A-3D show nanostructures made with conventional and gapless stencil lithography. FIGS. 3A and 3B show gold nanodisks made with conventional and gapless stencil lithography, respectively. The gold nanodisks in FIG. 3B are much crisper than those in FIG. 3A. Similarly, FIGS. 3C and 3D show bifunctional metasurfaces made with conventional and gapless stencil lithography, respectively. Again, the nanostructures fabricated with gapless stencil lithography appear much neater than those made with conventional stencil lithography.

Gapless stencil lithography also enables new capabilities: because the nanostructures and the stencil are transferrable, they can be stacked to create three-dimensional structures (e.g., photonic crystals) that may be more difficult or even impossible to make using conventional techniques. For example, arrays of nanostructures of the same or different materials, shapes, sizes, geometries, and/or pitches can be stacked on top of each other, possibly at different offsets and/or angles to create more complex, layered structures. Similarly, different stencils can be stacked on top of each other to create more complex, layered structures as described above with respect to FIGS. 2A-2E. Stencils and nanostructures can also be stacked on top of each other. Examples of these structures include but are not limited to twisted photonic crystal slabs, multilayer (e.g., bilayer or trilayer) metasurfaces, and double photonic crystal slab cavities.

Plasmonic Nanostructures Made with Gapless Stencil Nanofabrication

To demonstrate the effectiveness of gapless stencil nanofabrication techniques, we designed and made plasmonic nanostructures whose resonances we tuned to either the excitation energy of the laser or to the emission energy of the material of interest. Because we are also interested in polarization-dependent spectroscopy, we fabricated nanodisk resonator arrays with a large enough unit cell so that there are no plasmonic gap modes that break the in-plane rotational symmetry.

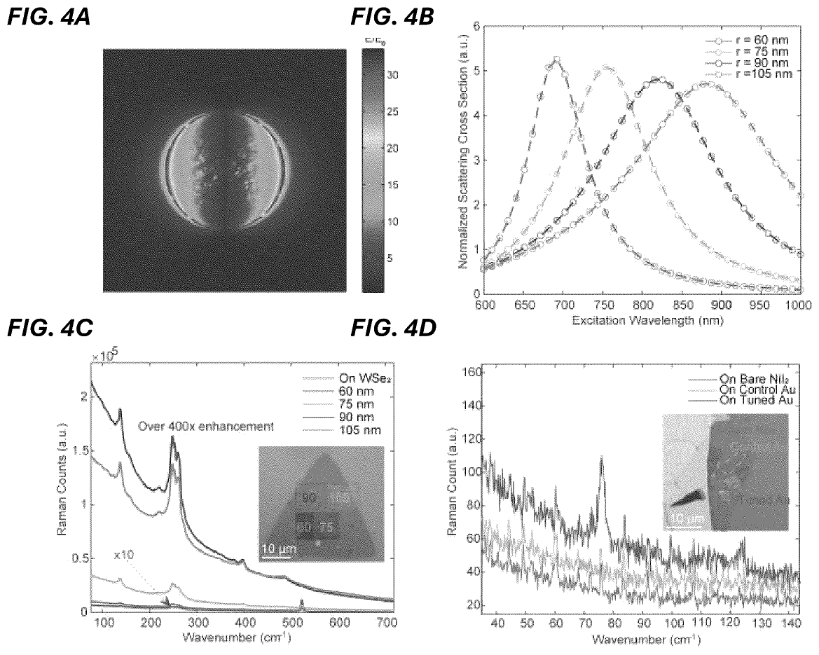

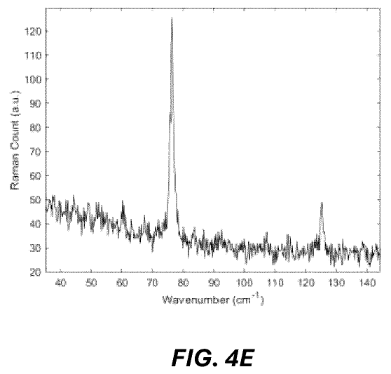

FIGS. 4A-4D illustrate Raman enhancement due with transferred plasmonic arrays made using gapless stencil lithography. FIG. 4A shows a simulation performed using a boundary element method solver, MATLAB MNP-BEM, of electric field enhancement in a plane 0.7 nm below a gold nanodisk with a 20 nm thickness and 90 nm radius illuminated by a plane wave at a wavelength of 785 nm. FIG. 4B shows wavelength-dependent scattering cross-sections normalized to the nanodisk area for four sets of arrays of nanodisks with a thickness of 20 nm and different radii. FIG. 4B shows that the resonance of the plasmonic nanostructures depends on the dielectric function of the underlying substrate and the exact shape of the nanodisks, which is susceptible to slight changes during the transfer.

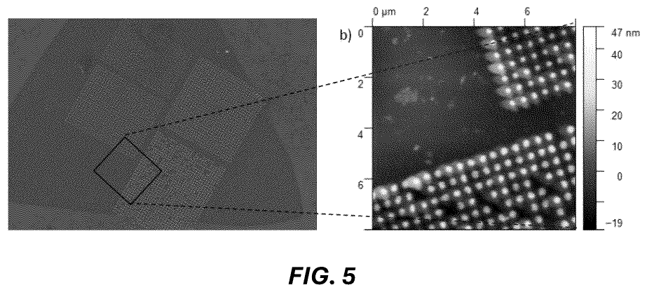

FIG. 5 shows an atomic force microscope (AFM) scan (left; close-up of SEM image at right) of the nanodisks used for the measurements shown in FIG. 4B. When gold is annealed during the polycarbonate (PC) transfer, the thickness and, hence, the quality, of the nanodisks are modified. This wetting appears more pronounced when the nanodisk radius is smaller. For example, the nanodisks with a radius of r=105 nm had an average maximum height of 30 nm, while this number was around 35 nm for r=75 nm nanodisks. This may be the biggest factor determining the quality of the nanostructures as plasmonic antennas. This also provides tunability of the plasmon resonance: the r=112 nm nanodisks used to demonstrate the Purcell effect performed better when we measured the Raman spectrum using 785 nm excitation after an annealing session at 200° C. for 6 hours, possibly because the aspect ratio shifts the maximum of scattering cross section.

We transferred the fabricated nanostructures onto a monolayer tungsten diselenide (WSe₂) sample and measured the Raman spectrum on and off the nanoarrays using 785 nm excitation. FIG. 4C shows the results, with an optical image in the inset (an SEM image of these results appears in FIG. 1B). The low wavenumber tail is the intralayer exciton of WSe₂. The maximum enhancement factor is around four hundred, coming from nanodisks with 90 nm radius. This number is the ratio of Raman counts on and off the nanostructures without any normalization to an effective area, which could increase the enhancement factor by another order of magnitude. The trend and the qualitative figure of merit of the enhancement factor is in line with the simulations.

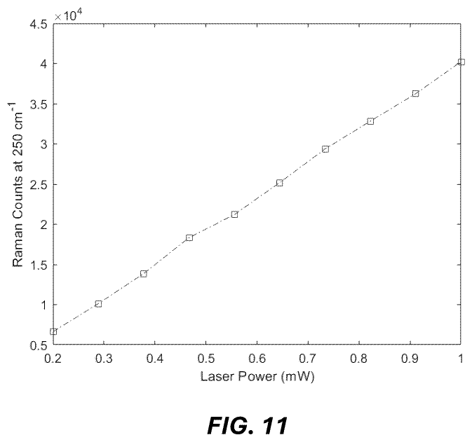

Keeping the excitation wavelength constant and changing the radii of the nanodisks effectively tunes how close the excitation wavelength is to the localized surface plasmon resonance (LSPR) of the nanostructures. Both the simulations and the experiments show that the LSPR energy of the nanodisks with 90 nm radius closely matches the photoexcitation energy, resulting in maximum enhancement factor due to both near-field enhancement and an enhanced spontaneous emission rate. FIG. 11 is a plot of the excitation power dependence of the Raman intensities.

This enhancement is spatially selective in out-of-plane direction: nominally, the silicon phonon peak at 520 cm⁻¹ is of the same order of magnitude with the phonon peaks of WSe₂. The nanodisks effectively turn the plane wave into a dipole excitation, which is concentrated around the top surface, resulting in an enhanced amount of signal from the sample with respect to the substrate—in FIG. 4C, even the higher-order phonon peaks at 390 cm⁻¹ and 485 cm⁻¹ are visible while the silicon peak at 520 cm⁻¹ virtually vanishes. This effect could be very valuable in optical studies of samples with low Raman cross sections, where the Raman signal is washed away by the substrate, or in distinguishing the origin(s) of Raman peaks of separate samples that are stacked vertically. The same method can be used to yield a Raman enhancement at 532 nm excitation. Gold may not be a suitable choice as the plasmonic material due to an interband transition very close to the excitation wavelength, so we used silver with a modified thickness and radius and observed a roughly 30-fold enhancement of the Raman signal from WSe₂.

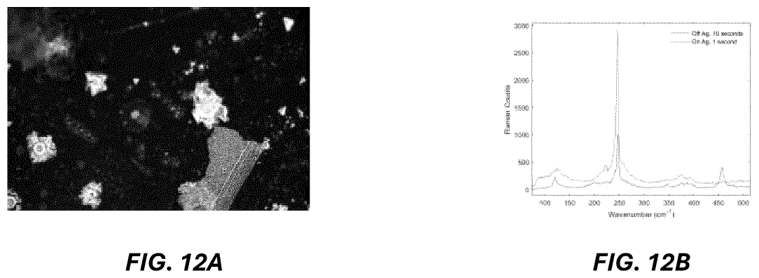

FIGS. 12A and 12B illustrate using silver nanodisks to enhance the Raman signal from WSe₂. FIG. 12A is an optical micrograph of the transferred Ag nanodisks (radius=70 nm, thickness=38 nm) on monolayer WSe₂ on a quartz substrate. FIG. 12B is a plot of the Raman spectrum of the structure shown in FIG. 12A. The silver nanodisks enhance the E_{2g} mode by a factor of around 30. Silver is much harder to work with than gold due to the difficulty in obtaining high-resolution nanostructures after the hot PC/PDMS transfer; annealing during the melting of PC affects silver nanostructures' shapes more than gold counterparts. As mentioned above, this could be remedied using dry transfer techniques or the gapless stencil lithography method shown in FIGS. 1C and 1D. Silver has a different work function than gold, so there might be more prominent charge transfer effects.

The straightforward integration of plasmonic nanostructures with air-sensitive materials is a particular advantage of our gapless stencil nanofabrication techniques over existing methods. Here, we demonstrate surface-enhanced signals from an air-sensitive material. We transferred two sets of gold nanodisk arrays—a tuned nanodisk array with radius and thickness (112 nm and 40 nm, respectively) tuned to 785 nm excitation and a control nanodisk array with a much larger radius (220 nm) not tuned to the excitation—onto a three-layer nickel iodide (NiI₂) sample. The transfer was performed from a sacrificial chip to the NiI₂ sample in a glove box because NiI₂ is air-sensitive. We used the second array to ensure that the enhancement comes mainly from the tuned size and not from charge transfer or related effects that could come from contact with gold. The inset of FIG. 4D is an optical image of the transferred nanodisks.

FIG. 4D shows raw Raman spectra of the bare NiI₂ sample (lower trace), NiI₂ sample with control nanodisks (middle trace), and NiI₂ sample with tuned nanodisks (upper trace) using 785 nm excitation, where the absorption cross-section was small. The Raman modes associated with bulk NiI₂ cannot be distinguished on either the control nanodisks or on the bare NiI₂ surface, even at the maximum laser power. On the tuned nanodisks, however, FIG. 4D shows the Eg and Ag modes at 76 cm⁻¹ and 123 cm⁻¹, respectively, like those visible in the Raman spectrum of bulk NiI₂ shown in FIG. 4E. Tuned plasmonic resonators, thus, help overcome the low Raman cross-section at 785 nm and enable the detection of Raman modes that are otherwise invisible.

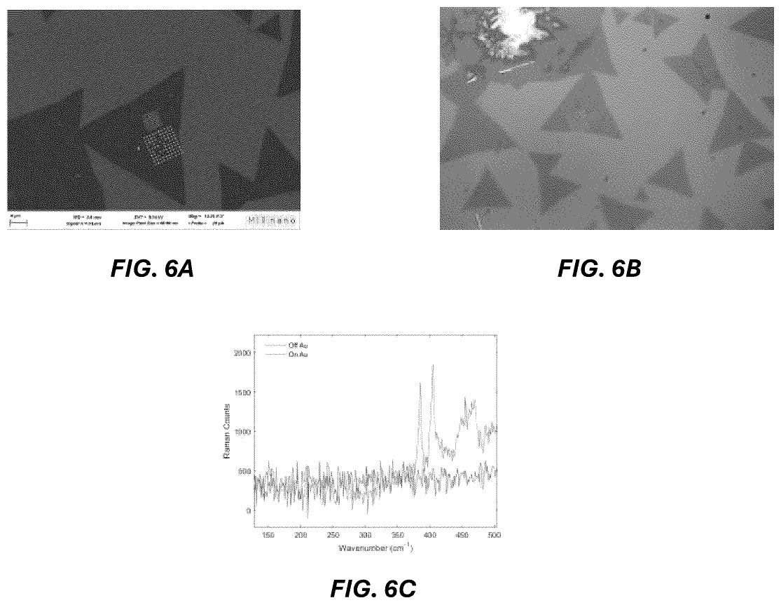

FIGS. 6A-6C show a demonstration of the same principle of enhancing detection of Raman modes using plasmonic nanodisks transferred to a MoS₂ sample. FIGS. 6A and 6B show SEM and optical images, respectively, of transferred plasmonic nanodisk arrays on MoS₂. FIG. 6C is a plot of Raman count versus wavenumber for bare MoS₂ (lower trace) and transferred plasmonic nanodisk arrays on MoS₂ (upper trace). Just like with a NiI₂ substrate, the nanodisks enable the detection of Raman signal from MoS₂, which has a very low Raman cross section at the excitation wavelength. Both A_{g} and E_{g} phonons, along with the 2LA phonon, are clearly visible when the spectrum is taken on tuned nanodisks. There is similarly no distinguishable signal from control nanodisks.

Resonators can also be used to modify the photonic local density of states (LDOS) without a near-field enhancement as demonstrated above, resulting in a modified spontaneous emission rate, also called the Purcell effect. This effect has been revealed in several different settings, some of which include GHz cavities for Rydberg atoms, plasmonic surface lattices for molecular dyes, and 2D/3D photonic crystals for quantum dots. Here, we demonstrate selectively enhancing PL signals from quenched excitons by the Purcell effect without near-field enhancement in a transition metal dichalcogenide (TMD) heterostructure.

Using the high degree of tunability enabled by our gapless stencil nanofabrication method, we fabricated two sets of arrays the same size with those transferred on NiI₂, whose dipole and quadrupole transitions, respectively, were tuned to the emission energy of intralayer excitons of WSe₂ at around 1.61 eV in our CVD-grown samples. We fabricated a heterostructure including WSe₂ at the bottom and MoS₂ on top, with a small twist that is not critical for our purposes.

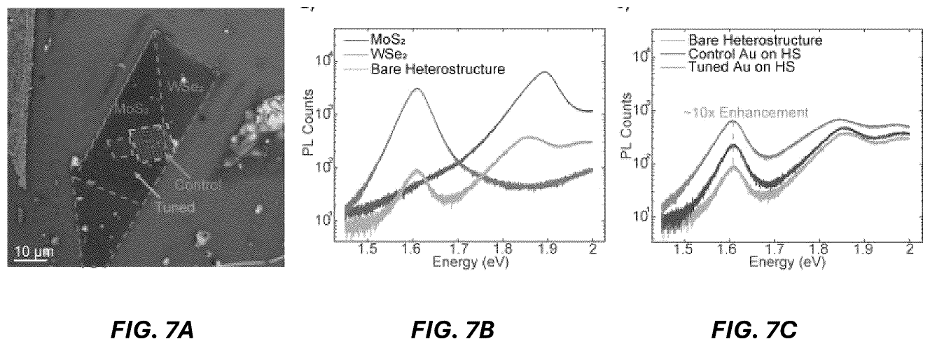

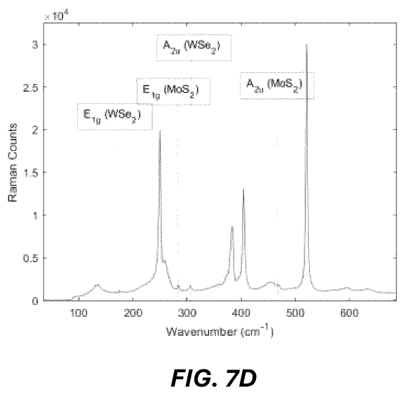

FIGS. 7A-7D illustrate the Purcell enhancement of quenched exciton PL due to transferred plasmonic arrays on a MoS₂/WSe₂ heterostructure. FIG. 7A is an optical micrograph of the heterostructures below the tuned and control plasmonic arrays, which are square arrays of gold nanodisks with radii of 112 nm and 220 nm, respectively. FIG. 7B is a plot of PL spectra of the MoS₂, WSe₂, and the MoS₂/WSe₂ heterostructure, all without any plasmonic arrays. FIG. 7C shows PL spectra of the bare MoS₂/WSe₂ heterostructure (bottom trace), control plasmonic array on the MoS₂/WSe₂ heterostructure (middle trace), and tuned plasmonic array on the MoS₂/WSe₂ heterostructure (top trace). The peak amplitude with the tuned plasmonic array is about ten times higher than that of the bare heterostructure. FIG. 7D shows the Raman spectrum generated with 532 nm excitation of the heterostructure in FIG. 7A.

FIG. 7B confirms that there is a strong coupling between the layers from observing the PL of quenched excitons due to type-II band alignment, and interlayer Raman modes that are activated only when the layers are coupled. After transferring the resonators onto the heterostructure, we measured the PL signal using 532 nm excitation. We observed an order-of-magnitude increase in the PL signal of quenched excitons of WSe₂ on tuned gold nanodisks. The near-field enhancement does not play a role in the enhancement; in fact, according to our simulations, both the control and tuned nanodisk arrays result in a reduction of the absolute electromagnetic field at the surface of WSe₂. We also ruled out charge transfer as the main mechanism for the PL enhancement, as the filling factors of both arrays are similar, which would be at odds with the large difference in the PL signal collection between the arrays.

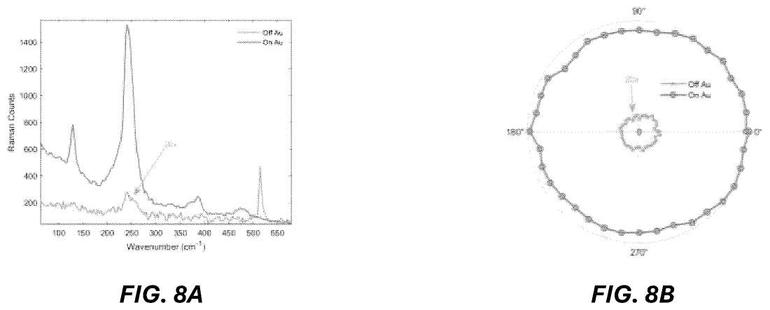

FIGS. 8A and 8B illustrate the Raman spectrum of the heterostructure in FIG. 7A, on and off the tuned plasmonic array. FIG. 8A shows more than two orders of magnitude enhancement of the WSe₂ Raman modes even when the nanodisks are on MoS₂. The polar plot in FIG. 8B indicates that the transferred nanodisks can be used in angular Raman studies as well because the enhancement does not change with the polarization of the incident light. That is, the enhancement of the 250 cm⁻¹ mode(s) is independent of the incident polarization.

### Electromagnetic Simulations of Plasmonic Nanostructures

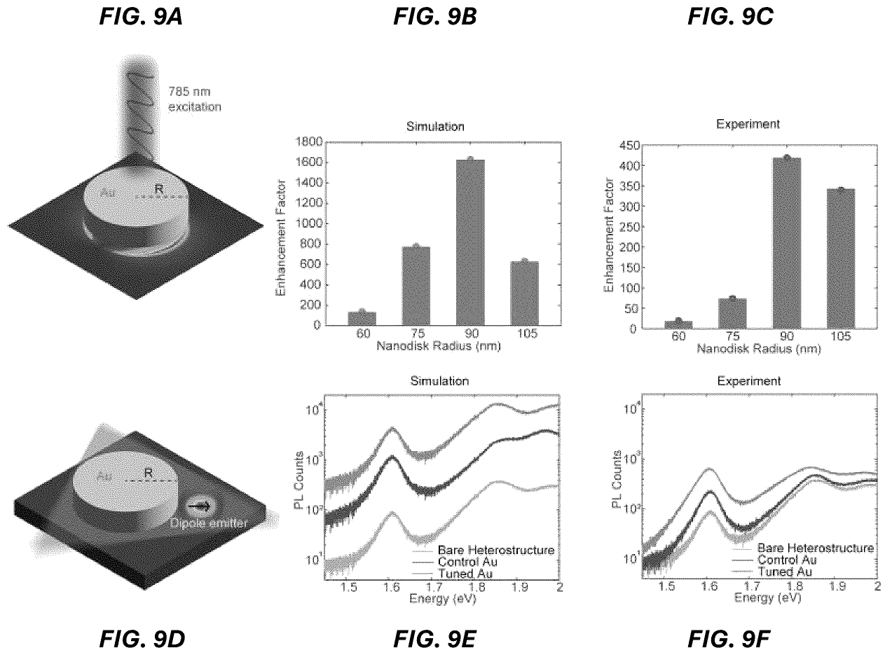

FIGS. 9A-9F illustrate electromagnetic simulations of the enhancement provided by plasmonic nanostructures made using gapless stencil lithography. Without being bound by any particular theory, electromagnetic simulations show that the enhancement comes from the enhanced LDOS created by placing tuned resonators near the excitons of WSe₂ and verify the SERS enhancement shown in FIG. 4B. For the near-field enhancement due to the plane-wave excitation, we modelled the nanodisks with thickness and radii extracted from AFM (FIG. 5) and SEM measurements, respectively, and placed them 1 nm above SiO₂. We solved for the E-field on the plane of WSe₂ and calculated the enhancement factor (EF) for SERS using the formula given below. For Purcell factor calculations, we employed in-plane dipole sources with varying emission wavelengths near the nanodisks on the surface where WSe₂ is supposed to be and measured the power emitted by the dipoles. The ratio of this power to the nominal power emitted by the same dipole in free space is equivalent to the Purcell effect:

$$F ≡ \frac{γ}{{γ}_{0}} = \frac{{P}_{tot}}{{P}_{0}} ,$$

where γ is the total modified decay rate, γ₀ is the spontaneous decay rate of the identical emitter in free space, Pₜₒₜ is the sum of radiated and dissipated power in the presence of a resonator, and P₀ is the radiated power of the dipole in free space. The SERS EF is given by:

$$EF ( λ ) = \frac{{\vert E \vert}^{2}}{{\vert {E}_{0} \vert}^{2}} \frac{γ}{{γ}_{0}} ,$$

where E is the E-field of a given point with the resonator in place, and E₀ is the E-field of the excitation. For Raman modes, with appropriate approximations for the radiation direction and the bandwidth of the plasmon bands, γ/γ₀ approximates |E|²/|E₀|², yielding the well-known |E|⁴ formula, EF(λ)∝|E|⁴/|E₀|⁴. Regardless, we conducted simulations for both with |E|⁴ formula and |E|²F calculation by integrating the EF(λ) for all points, taking into account the substrate interference and metallic losses.

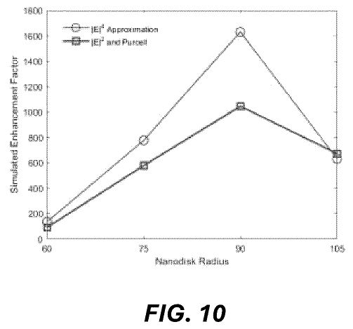

FIGS. 9B and 9E show the results with λ=785 nm and with a varying wavelength, respectively. We arrived at the simulated spectra by pointwise multiplying the wavelength-dependent averaged Purcell factor with the experimental data. FIG. 9B shows the |E|⁴ results, and FIG. 10 shows a comparison of the |E|⁴ results and an explicit calculation of the Purcell factor. Simulations successfully capture the trends but fall short on the exact enhancement values, especially at lower wavelengths. This may be due to the annealing/wetting of the nanodisks with the PC/PDMS transfer (see FIG. 5, described above), which can be remedied by cold/dry transfer techniques or the alternative fabrication technique illustrated in FIGS. 1C and 1D.

Making Plasmonic Nanostructures Made with Gapless Stencil Nanofabrication

Nanofabrication. The silicon nitride membranes used for the stencils described above were purchased from Norcada (TA301X and TA301A) and milled with Raith Velion FIB-SEM at the Characterization.Nano of MIT.nano. Gold deposition was performed using an electron beam evaporator (EBcam-AJA, Aja Model ATC 20×20×36) at MIT.nano. The SEM images were taken using a Zeiss Gemini 450 at the Characterization.nano of MIT.nano.

Crystal Growth and Transfer. Monolayer MoS₂ and WSe₂ flakes were both synthesized via liquid-phase, precursor-assisted chemical vapor deposition (CVD). In the case of MoS₂, MoO₃ (25 mg) and KI (25 mg) were dissolved in ammonium hydroxide (20 mL), and the precursor solution was then spin-coated onto a piece of SiO₂/Si substrate. During the synthesis process, the precursor-coated substrate was loaded into a 1-inch tube furnace and the precursor was sulfurized at 700° C. for 5 min. Argon (20 sccm) was used as the carrier gas throughout the process. For the synthesis of WSe₂, ammonium metatungstate hydrate (100 mg) and NaCl (25 mg) were dissolved in water (10 mL), and the precursor solution (1 μL) was then drop-casted onto a piece of SiO₂/Si substrate. During the synthesis process, the precursor-coated substrate was loaded into a 1-inch tube furnace and the precursor was selenized at 850° C. for 5 minutes. Argon (100 sccm) was flowing throughout the process (i.e., temperature ramping, growth, and cooling stages), while hydrogen (5 sccm) was introduced during the growth stage at 850° C. Single-crystal NiI₂ was grown by chemical vapor transport, from elemental precursors with a molar ratio Ni:I=1:2, at a temperature gradient 700° C. to 500° C.

We used a low-adhesion blue tape to exfoliate the crystal. We used hot PC/PDMS transfer for the transfers, including the transfer of MoS₂ on WSe₂. WSe₂ and MoS₂ sample thicknesses were determined by PL and Raman spectroscopy. The NiI₂ sample thickness was determined by atomic force microscopy (AFMWorkshop HR), which was performed inside a separate nitrogen-filled glovebox (O₂, <100 ppm; H₂O, <1 ppm), using a silicon probe in tapping mode.

Raman and PL Spectroscopy Measurements. Raman data presented in FIG. 4C (<50 μW, 1-second acquisition time), FIG. 12B (<500 μW, 1-10 second acquisition time), and FIGS. 7B and 7C (<1 mW, 10-second acquisition time) were taken using a Renishaw in Via Reflex Raman Microscope with a 100× objective in backscattering geometry. Raman data presented in FIG. 4D (<10 mW, 10-minute acquisition time), FIG. 4E, FIGS. 7B and 7C (<2 mW, 30-second acquisition time), and FIG. 12B (<10 mW, 5-minute acquisition time) were taken using a Horiba LabRAM HR Evolution Raman Spectroscopy Setup with a 50× objective in backscattering geometry. FIGS. 8A and 8B (<10 μW, 1-20 seconds for each polarization) were taken using a WITec alpha300 apyron Confocal Raman system with a 100× objective in a backscattering geometry.

Simulations. The simulations were carried out on MNP-BEM, a MATLAB toolbox. We used the templates demospecret8.m, demosprecret10.m, and demodipret10.m provided with MNPBEM14—and modified the geometries and the dielectric environment to fit our experiments. Gold dielectric data was taken from Johnson, P. B. & Christy, R. W. Optical Constants of the Noble Metals. Phys. Rev. B 6, 4370-4379 (1972), which is incorporated herein by reference in its entirety for all purposes. We also included the thin-film interference effect (which reduces the 785-nm excitation laser power incident on the sample to about 65%, calculated with the transfer matrix method) due to the 285 nm SiO₂/Si interface and metallic losses incurred after the Raman scattering.

### CONCLUSION

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize or be able to ascertain, using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

Also, various inventive concepts may be embodied as one or more methods, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the components so conjoined, i.e., components that are conjunctively present in some cases and disjunctively present in other cases. Multiple components listed with “and/or” should be construed in the same fashion, i.e., “one or more” of the components so conjoined. Other components may optionally be present other than the components specifically identified by the “and/or” clause, whether related or unrelated to those components specifically identified. Thus, as a non-limiting example, a reference to “A and/or B”, when used in conjunction with open-ended language such as “comprising” can refer, in one embodiment, to A only (optionally including components other than B); in another embodiment, to B only (optionally including components other than A); in yet another embodiment, to both A and B (optionally including other components); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of components, and, optionally, additional unlisted items. Only terms clearly indicated to the contrary, such as “only one of” or “exactly one of,” or, when used in the claims, “consisting of,” will refer to the inclusion of exactly one component of a number or list of components. In general, the term “or” as used herein shall only be interpreted as indicating exclusive alternatives (i.e., “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more components, should be understood to mean at least one component selected from any one or more of the components in the list of components, but not necessarily including at least one of each and every component specifically listed within the list of components and not excluding any combinations of components in the list of components. This definition also allows that components may optionally be present other than the components specifically identified within the list of components to which the phrase “at least one” refers, whether related or unrelated to those components specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including components other than B); in another embodiment, to at least one, optionally including more than one, B, with no A present (and optionally including components other than A); in yet another embodiment, to at least one, optionally including more than one, A, and at least one, optionally including more than one, B (and optionally including other components); etc.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures. Section 2111.03.

1. A method of fabricating nanostructures on a substrate, the method comprising:
forming a stencil for the nanostructures;
placing the stencil in direct contact with a surface of the substrate;
depositing material through the stencil directly on the surface of the substrate to form the nanostructures on the surface of the substrate; and
removing the stencil from the substrate without removing the nanostructures from the surface of the substrate.

2. The method of claim 1, wherein forming the stencil comprises:
disposing a membrane in direct contact with the surface of the substrate; and
patterning apertures for the nanostructures in the membrane to form the stencil.

3. The method of claim 2, wherein patterning the stencil comprises focused ion beam milling of the apertures in the membrane.

4. The method of claim 2, wherein the membrane comprises at least one of silicon nitride or silicon.

5. The method of claim 2, wherein the membrane has a thickness of about 30 nm to about 500 nm.

6. The method of claim 1, wherein removing the stencil comprises lifting the stencil off the surface of the substrate with a piece of tape.

7. The method of claim 1, wherein the substrate is a first substrate, and further comprising:
transferring the nanostructures from the surface of the first substrate to a surface of a second substrate.

8. The method of claim 7, wherein the first substrate comprises at least one of silicon or silicon oxide and the second substrate comprises at least one of a two-dimensional material or an air-sensitive material.

9. The method of claim 1, wherein the substrate is a first substrate, and further comprising:
placing the stencil directly on a surface of a second substrate;
depositing material through the stencil directly on the surface of the second substrate to form nanostructures on the surface of the second substrate; and
removing the stencil from the second substrate without removing the nanostructures from the surface of the second substrate.

10. The method of claim 1, wherein the stencil is a first stencil, and further comprising:
disposing a second stencil directly on the first stencil.

11. The method of claim 10, wherein disposing the second stencil directly on the first stencil comprises rotating the second stencil with respect to the first stencil about an axis perpendicular to the surface of the substrate and/or translating the second stencil with respect to the first stencil in a direction parallel to the surface of the substrate.

12. A method of fabricating nanostructures on a sample, the method comprising:
forming a stencil for the nanostructures on a sacrificial substrate;
removing the stencil from the sacrificial substrate;
placing the stencil in direct contact with a surface of the sample;
depositing material through the stencil directly on the surface of the sample to form the nanostructures; and
removing the stencil from the sample.

13. The method of claim 12, wherein forming the stencil comprises patterning holes for the nanostructures in a membrane.

14. The method of claim 13, wherein the membrane comprises silicon nitride.

15. The method of claim 13, wherein the membrane has a thickness of about 30 nm to about 500 nm.

16. The method of claim 12, wherein removing the stencil from the sacrificial substrate comprises lifting the stencil off the sacrificial substrate with a piece of adhesive tape.

17. The method of claim 16, further comprising:
forming additional nanostructures with the stencil on another substrate.

18. The method of claim 12, wherein the stencil is a first stencil, and further comprising:
disposing a second stencil directly on the first stencil.

19. The method of claim 18, wherein depositing the material through the first stencil comprises depositing the material through second stencil.

20. The method of claim 18, wherein disposing the second stencil directly on the first stencil comprises rotating the second stencil with respect to the first stencil about an axis perpendicular to the surface of the sample and/or translating the second stencil with respect to the first stencil in a direction parallel to the surface of the sample.
